(19) United States
(12) Patent Application Publication
(10) Pub. No.: US 2025/0275254 A1
(43) Pub. Date: Aug. 28, 2025

(54) Electro Static Discharge (ESD) Protection Apparatus, ESD Protective Semiconductor Device, and ESD Protection Method

(71) Applicant: Joulwatt Technology Co., Ltd., Hangzhou (CN)

(72) Inventors: Feng YAO, Hangzhou (CN); Sunze ZHOU, Hangzhou (CN)

(73) Assignee: Joulwatt Technology Co., Ltd., Hangzhou (CN)

(21) Appl. No.: 19/036,081

(22) Filed: Jan. 24, 2025

(30) Foreign Application Priority Data
Feb. 27, 2024 (CN) 202410216951.6

(51) Int. Cl. H10D 89/60

(52) U.S. Cl. CPC H10D 89/601

(57) ABSTRACT

An electro-static discharge (ESD) protection apparatus is connected to a pin of a chip, and includes: an ESD protective semiconductor device including a drain electrode connected to the pin and a source electrode connected to a reference ground, and configured to discharge a current on the pin; and a comparator circuit, connected between the pin and a gate electrode of the ESD protective semiconductor device, and configured to: acquire a voltage on the pin to obtain a voltage signal, compare the voltage signal with a reference signal of a negative voltage, and control an on-state of the ESD protective semiconductor device according to a comparison result. When the voltage signal is less than the reference signal, a channel between the source electrode and the drain electrode of the ESD protective semiconductor device is opened by the comparator circuit.

### CROSS REFERENCE TO THE RELATED APPLICATIONS

This application is based upon and claims priority to Chinese Patent Application No. 202410216951.6, filed on Feb. 27, 2024, the entire contents of which are incorporated herein by reference.

### TECHNICAL FIELD

The present disclosure relates to the technical field of semiconductors, and in particular to an electro-static discharge (ESD) protection apparatus, an ESD protective semiconductor device, and an ESD protection method.

### BACKGROUND

As an objective natural phenomenon, ESD occurs throughout whole cycles of products. The ESD is imperceptible to human bodies but poses a serious threat to integrated circuit (IC) products. During manufacture, encapsulation, testing to application of chips, certain charges are accumulated inside and outside the chips to cause the ESD at any time. Hence, each pin is provided with an ESD protection device in design of the chips. For example, an N-channel metal-oxide-semiconductor (NMOS) structure or a P-channel metal-oxide-semiconductor (PMOS) structure is used as the ESD protection device.

FIG. 1 illustrates a schematic view of an ESD protection apparatus of a chip in the prior art. As shown in FIG. 1, the ESD protection apparatus 20 is connected to pin 10 of the chip. The ESD protection apparatus 20 is, for example, an NMOS device. Drain electrode Drain of the NMOS device is connected to the pin 10, and body region Body, source electrode Source and gate electrode Gate of the NMOS device are grounded. Tub region Tub surrounding an active region of the NMOS device is also grounded. In application of the chip, each pin suffers a current surge. For example, in the latch-up experiment, a current is typically drawn out by the pin 10, and according to a direction of current, the drawn current is considered as a negative current. When the pin 10 suffers the negative current surge, due to intrinsic structural characteristics of the NMOS device 20, some parasitic structures such as the triode are generated in the NMOS device. A current is drawn by the drain electrode Drain to the internal tub region Tub to cause a large current path or even form a latch-up effect to damage the chip. Therefore, the ESD protective performance of the prior NMOS device is still to be improved.

### SUMMARY

In view of the above problems, an objective of the present disclosure is to provide an ESD protection apparatus, an ESD protective semiconductor device, and an ESD protection method, to solve the problems in the prior art.

An aspect of the present disclosure provides an ESD protection apparatus connected to a pin of a chip, and including: an ESD protective semiconductor device, configured to discharge a current generated on the pin, and including a source electrode, a drain electrode, and a gate electrode, where the drain electrode is connected to the pin, and the source electrode is connected to a reference ground; and a comparator circuit, connected between the pin and the gate electrode of the ESD protective semiconductor device, and configured to: acquire a voltage on the pin to obtain a voltage signal, compare the voltage signal with a reference signal, and control an on-state of the ESD protective semiconductor device according to a comparison result. When the voltage signal is less than the reference signal, a negative current generated on the pin reaches a threshold current, and a channel between the source electrode and the drain electrode of the ESD protective semiconductor device is opened by the comparator circuit; and the reference signal is a negative voltage.

Optionally, the ESD protective semiconductor device is an NMOS device, and the reference signal is between −0.1 V and −2 V.

Optionally, the comparator circuit includes: a comparator, where a positive input terminal and a negative input terminal of the comparator are respectively configured to receive the reference signal and the voltage signal, and an output terminal of the comparator is connected to the gate electrode; and a resistor, connected between the pin and the negative input terminal of the comparator, and configured to: acquire the voltage on the pin to obtain the voltage signal, and transmit the voltage signal to the comparator.

Another aspect of the present disclosure provides an ESD protective semiconductor device connected between a pin of a chip and a reference ground, and including: a substrate; a first well region, distributed in the substrate, and having a first doping type; a second well region, located in the first well region, and having a second doping type, where the first doping type is opposite to the second doping type; a plurality of first injection regions and a plurality of second injection regions, distributed at intervals in the first well region and the second well region and in gaps between the well regions, and respectively having the first doping type and the second doping type; and a field plate layer, located on the second well region, and configured to lead out a gate electrode, where a drain electrode and a source electrode are respectively led out from the first injection regions adjacent to two sides of the field plate layer. The drain electrode is connected to the pin, the source electrode is connected to the reference ground, and the gate electrode is configured to receive a control signal. When a voltage signal on the pin is less than a reference signal of a preset negative voltage, a channel between the source electrode and the drain electrode is opened through the control signal.

Optionally, the ESD protective semiconductor device is an NMOS device; the first doping type is N-type doping; and the second doping type is P-type doping.

Optionally, the reference signal is between −0.1 V and −2 V.

Optionally, in response to a positive current generated on the pin, a first parasitic triode among the drain electrode, the second well region and the first well region is turned on to discharge the current.

Optionally, in response to a negative current generated on the pin, a first parasitic triode among the first well region, the second well region and the drain electrode is turned on, and alternatively, a second parasitic triode among the first injection region in the substrate, the substrate and the first well region, and the first parasitic triode among the first well region, the second well region and the drain electrode are turned on at the same time, thereby forming a first current discharge path to discharge the current.

Optionally, when the voltage signal on the pin is less than the reference signal of the preset negative voltage, the channel between the source electrode and the drain electrode is opened to form a second current discharge path.

Another aspect of the present disclosure provides an ESD protection method applied to the ESD protective semiconductor device, and including: acquiring the voltage on the pin to obtain the voltage signal; comparing the voltage signal with the reference signal of the preset negative voltage, and controlling an on-state of the ESD protective semiconductor device according to a comparison result. When the voltage signal is less than the reference signal, a negative current generated on the pin reaches a threshold current, and the channel between the source electrode and the drain electrode of the ESD protective semiconductor device is opened.

According to the ESD protection apparatus, the ESD protective semiconductor device, and the ESD protection method provided by the present disclosure, the gate electrode of the ESD protective semiconductor device is configured to receive the control signal. The control signal is associated with the current on the pin. When the voltage signal on the pin is less than the reference signal of the preset negative voltage, the negative current generated on the pin reaches the threshold current, and the channel between the source electrode and the drain electrode of the ESD protective semiconductor device is opened through the control signal, thereby increasing the current discharge path from the source electrode to the drain electrode. That is, when the pin suffers a large negative current surge, not only can the current be discharged by a parasitic structure in the ESD protective semiconductor device, but also the channel can be opened to form another discharge path. This prevents a large current in the ESD protective semiconductor device to damage the chip, effectively prevents the latch-up effect, and improves the ESD protection performance.

Further, in response to the positive current surge on the pin, the parasitic structure can form the current discharge path from the pin to the reference ground. In response to the negative current surge on the pin, the parasitic structure can also form a current discharge path from a power supply electrode to the pin. In response to the larger negative current surge on the pin, the channel between the source electrode and the drain electrode can further be opened to increase the current discharge path from the reference ground to the pin. This enhances the ESD protection performance and the latch-up prevention performance of the ESD protective semiconductor device and the ESD protection apparatus, protects the ESD protective semiconductor device well in the latch-up experiment, and improves the discharge capacity of the ESD protective semiconductor device in normal ESD.

### BRIEF DESCRIPTION OF THE DRAWINGS

With reference to the description of the accompanying drawings below on the embodiments of the present disclosure, the above and other objectives, features and advantages of the present disclosure will become more apparent.

FIG. 1 illustrates a schematic view of an ESD protection apparatus of a chip according to a prior art;

FIG. 2 illustrates a schematic structural view of an ESD protection apparatus according to an embodiment of the present disclosure;

FIG. 3 illustrates a schematic sectional view of an ESD protective semiconductor device according to an embodiment of the present disclosure;

FIG. 4 illustrates a schematic view of an equivalent circuit of the ESD protective semiconductor device in FIG. 3; and

FIG. 5 illustrates a schematic flowchart of an ESD protection method according to an embodiment of the present disclosure.

### DETAILED DESCRIPTION OF THE EMBODIMENTS

Various embodiments of the present disclosure will be described in more detail below with reference to the accompanying drawings. In the various accompanying drawings, the same elements are designated by the same or similar reference numerals. For clarity, all parts in the accompanying drawings are not drawn to scale. In addition, some well-known parts may not be shown. For the sake of brevity, a semiconductor structure obtained by implementing a plurality of steps may be shown in one figure.

In description on the structure of the device, when a layer and a region is located “on” or “above” another layer and another region, the layer and the region may be directly located on the another layer and the another region, or there is further other layer or region between the layer and the region, and the another layer and the another region. Meanwhile, if the device is turned over, the layer and the region are located “under” or “below” the another layer and the another region. For a case where the layer and the region are directly located on the another layer and the another region, the expression “A is directly located on B” or “A is located on B and adjacent to the B” is used herein. In the present disclosure, the expression “A is directly located in B” indicates that the A is located in the B, and the A is directly adjacent to the B, rather than that the A is located in a doped region of the B. Unless otherwise specified hereinafter, each layer or region of the semiconductor device may be made of a material known by those skilled in the art.

Specific implementations of the present disclosure are described in more detail below with reference to the accompanying drawings and embodiments.

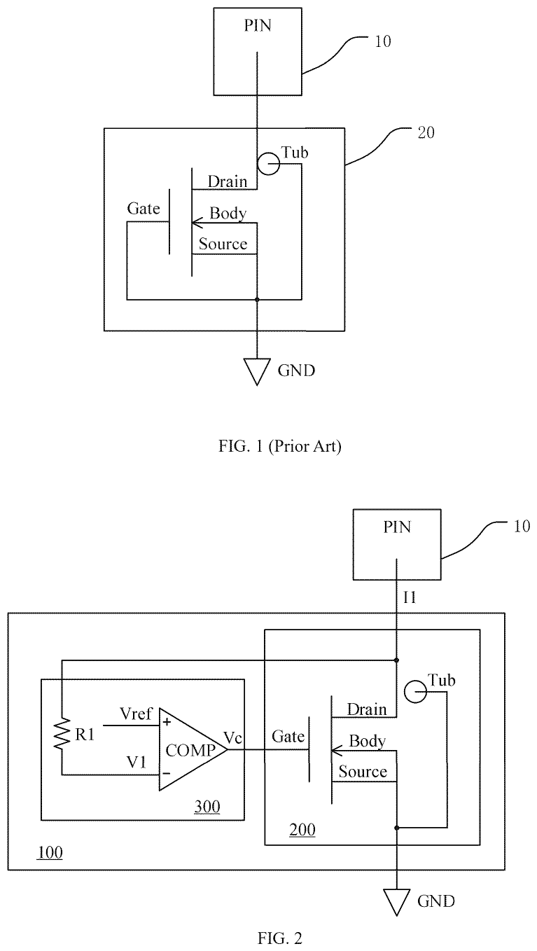

FIG. 2 illustrates a schematic structural view of an ESD protection apparatus according to an embodiment of the present disclosure.

As shown in FIG. 2, the ESD protection apparatus 100 provided by the embodiment of the present disclosure is connected to pin 10 of a chip, and configured to realize ESD protection on the pin. The ESD protection apparatus 100 includes ESD protective semiconductor device 200 and comparator circuit 300. The ESD protective semiconductor device 200 is configured to discharge a current generated on the pin 10. The ESD protective semiconductor device is an NMOS device, and includes source electrode Source, drain electrode Drain, and gate electrode Gate. The drain electrode Drain is connected to the pin 10. The source electrode Source is connected to a reference ground. The gate electrode Gate is connected to the comparator circuit 300, and configured to receive control signal Vc output from the comparator circuit 300. The comparator circuit 300 is connected between the pin 10 and the gate electrode Gate of the ESD protective semiconductor device 200. The comparator circuit 300 is configured to acquire voltage signal V1 on the pin, compare the voltage signal with reference signal Vref, and output different control signals Vc according to a comparison result to control an on-state of the ESD protective semiconductor device 200. Specifically, when the voltage signal V1 is less than the reference signal Vref, a negative current generated on the pin 10 reaches a threshold current. By this time, a channel between the source electrode and the drain electrode of the ESD protective semiconductor device 200 is opened by the comparator circuit 300. The reference signal Vref corresponds to a negative voltage.

Further, the comparator circuit 300 includes resistor R1 and comparator COMP. The resistor R1 is connected between the pin 10 and a negative input terminal of the comparator COMP, and configured to acquire a voltage on the pin 10 to obtain the voltage signal V1. For example, the resistor can obtain the voltage signal V1 according to current I1 on the pin 10, and transmit the voltage signal to the comparator COMP. A positive input terminal and the negative input terminal of the comparator CMP are respectively configured to receive the reference signal Vref and the voltage signal V1. An output terminal of the comparator CMP is connected to the gate electrode Gate of the ESD protective semiconductor device 200, and configured to output the control signal Vc. Therefore, when the voltage signal V1 is less than the reference signal Vref, the comparator circuit 300 outputs the high-level control signal Vc to open the channel between the source electrode and the drain electrode of the ESD protective semiconductor device 200, namely, to turn on the ESD protective semiconductor device 200. Further, the reference signal Vref is set as the negative voltage. When the negative current on the pin 10 exceeds a certain value, the voltage signal V1 is less than the reference signal Vref, and thus the channel between the source electrode and the drain electrode of the ESD protective semiconductor device 200 is opened. The reference signal may be between −0.1 V and −2 V, and may be, for example, −0.2 V. Alternatively, when the current I1 on the pin 10 is less than −200 mA, the channel between the source electrode and the drain electrode of the ESD protective semiconductor device 200 is opened.

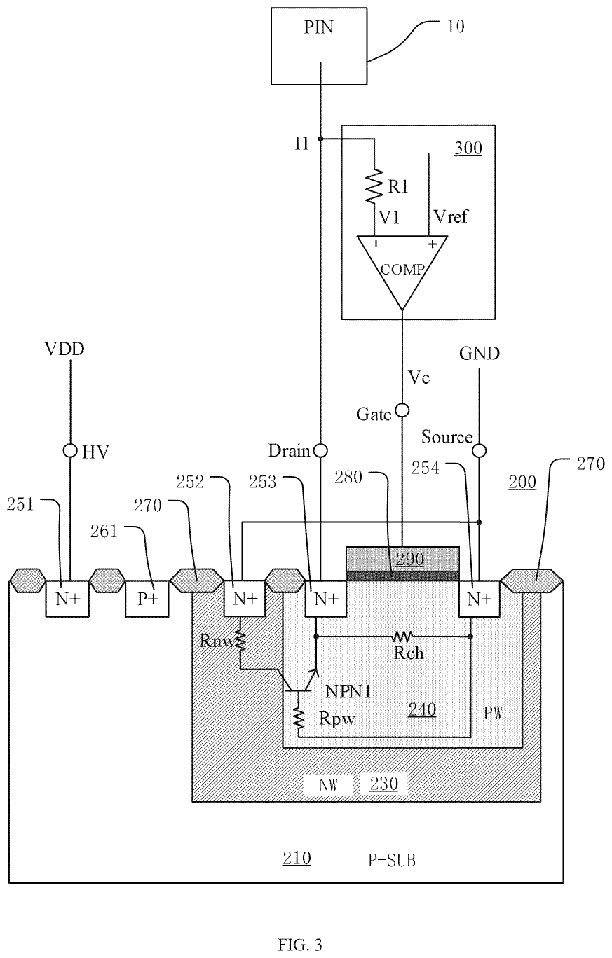

In the embodiment, the ESD protective semiconductor device 200 is the NMOS device, and is taken as the ESD protection device. In response to a current surge on the pin, a potential on the drain electrode Drain changes, such that a parasitic structure in the ESD protective semiconductor device 200 is turned on, for example, a parasitic triode is turned on, thereby discharging the ESD current. For example, a well region and a substrate are further provided outside an active region (the gate electrode, the source electrode and the drain electrode) of the ESD protective semiconductor device 200. The well region may be tub region Tub. The tub region Tub is connected to the reference ground. In response to a negative current on the pin, a current may be drawn from the tub region Tub. The current when the internal parasitic structure is turned on is large, or even the latch-up effect is caused. When the channel between the source electrode and the drain electrode of the ESD protective semiconductor device 200 is opened, a current discharge channel from the source electrode to the drain electrode is increased to improve the ESD protection performance and the latch-up prevention performance of the device. Further, before mass production of the ESD protection apparatus 100, a latch-up experiment is conducted to test the latch-up prevention performance. A large negative current is applied to the pin 10. In order not to damage the chip, the ESD protection apparatus 100 in the embodiment may be used, thereby opening the channel between the source electrode and the drain electrode of the ESD protective semiconductor device 200 to shunt the large current. Certainly, in response to a large negative current in normal ESD protection, the channel between the source electrode and the drain electrode of the ESD protective semiconductor device 200 may also be opened. The ESD protective semiconductor device 200 in the embodiment is described below in detail with reference to FIG. 3.

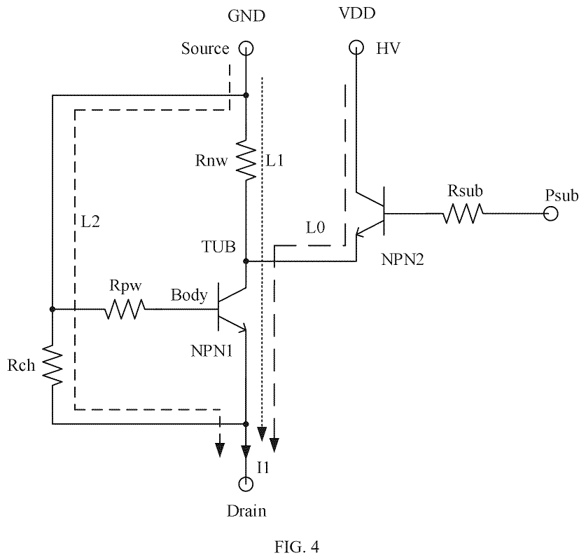

FIG. 3 illustrates a schematic sectional view of an ESD protective semiconductor device according to an embodiment of the present disclosure. FIG. 4 illustrates a schematic view of an equivalent circuit of the ESD protective semiconductor device in FIG. 3.

As shown in FIG. 3, the ESD protective semiconductor device 200 in the embodiment includes: substrate 210, first well region 230, and second well region 240. The substrate 210 is, for example, a silicon substrate, and may be P-type doping (P-SUB). The first well region 230 extends inward from an upper surface of the substrate 210, and has a first doping type. The second well region 240 is located in the first well region 230, and extends inward, for example, from an upper surface of the first well region 230. The first well region 230 surrounds the second well region 240, and is an integral structure. Alternatively, a transverse buried layer is formed in the substrate 210, and then a longitudinal well region is formed. The transverse buried layer and the longitudinal well region are integrated to obtain the first well region 230 with a “U”-shaped sectional view. The second well region 240 is further formed in the substrate 210 surrounded by the first well region 230. From a top view, the first well region 230 may be annular, such that the first well region 230 surrounds a sidewall and a bottom of the second well region 240. The first well region 230 may be a tub overall, and may also be called a tub region. The first well region 230 has the first doping type. The second well region 240 has a second doping type. The first doping type is opposite to the second doping type.

Further, a plurality of field oxide layers 270 are provided in well regions and between the well regions. Each field oxide layer 270 is partially located in the substrate 210, so as to separate each well region. A plurality of first injection regions and a plurality of second injection regions are formed along gaps of the field oxide layers 270 by injection. That is, the plurality of first injection regions and the plurality of second injection regions are distributed at intervals in the first well region 230 and the second well region 240 and in gaps between the well regions, and respectively have the first doping type and the second doping type. The ESD protective semiconductor device 200 further includes field plate layer 290. The field plate layer 290 is located on the second well region 240. Gate oxide layer 280 is formed under the field plate layer 290. The field plate layer 290 is, for example, a polycrystalline silicon layer. The gate oxide layer 280 covers a part of an upper surface of the second well region 240. For example, the first doping type is N-type doping, and the second doping type is P-type doping. The first well region 230 is an N-type well region (NW), the second well region 240 is a P-type well region (PW), the first injection region is an N+ injection region, and the second injection region is a P+ injection region.

Further, two sides of the field plate layer 290 in the second well region 240 each are provided with one first injection region (N+ injection region), namely the N+ injection region 253 and the N+ injection region 254. Further, a side of the N+ injection region 254 away from the field plate layer 290 may further be provided with one P+ injection region. At least the N+ injection region 252 is provided in the first well region 230. The P+ injection region 261 and the N+ injection region 251 adjacent to the P+ injection region 261 are provided in the substrate 210. Further, another N-type well region may further be formed in the substrate 210. The N+ injection region 251 is formed in the N-type well region. That is, the N+ injection region 251, the P+ injection region 261, the N+ injection region 252, the N+ injection region 253 and the N+ injection region 254 are sequentially spaced on an upper portion of the substrate 210.

The ESD protective semiconductor device 200 is connected between the pin 10 of the chip and the reference ground. According to the ESD protective semiconductor device 200, power supply electrode HV is led out from the internal N+ injection region 251. Gate electrode Gate is led out from the field plate layer 290. Drain electrode Drain and source electrode Source are respectively led out from the N+ injection region 253 and the N+ injection region 254 adjacent to the two sides of the field plate layer 290. The power supply electrode HV is configured to receive power supply voltage VDD. The gate electrode Gate is configured to receive control signal Vc. The drain electrode Drain is connected to the pin 10. The source electrode Source is connected to the reference ground GND.

Further, according to the ESD protective semiconductor device 200, the P+ injection region may further be provided in the second well region 240 to lead out body electrode Body. Tub electrode Tub is led out from the N+ injection region 252 in the first well region 230, and substrate electrode Psub is led out from the P+ injection region 261 in the substrate 210. The body electrode Body, the tub electrode Tub and the substrate electrode Psub may be connected to the reference ground.

The power supply electrode HV is configured to convert the power supply voltage VDD into a lower voltage for example, thereby supplying the low voltage to the ESD protective semiconductor device 200. The control signal Vc may be generated by external comparator circuit 300. When the voltage signal V1 on the pin 10 is less than a reference signal Vref of a preset negative voltage, a negative current generated on the pin reaches a threshold current. By this time, a channel between the source electrode and the drain electrode of the ESD protective semiconductor device 200 is opened through the control signal Vc output from the comparator circuit 300. The reference signal of the negative voltage may be, for example, between −0.1 V and −2 V, and may be, for example, −0.2 V.

Before the ESD protective semiconductor device 200 is used for ESD protection formally, different experiments are conducted to test performance of the ESD protective semiconductor device. For example, a latch-up experiment is conducted to test latch-up prevention performance of the ESD protective semiconductor device. In this case, a large negative current is to be applied to the pin 10. When the pin 10 suffers a negative current surge, parasitic triode NPN1 is formed among the N+ injection region 252, the first well region 230, the second well region 240 and the N+ injection region 253. Because of the negative current on the drain electrode Drain, the parasitic triode NPN1 is turned on to draw a current from the first well region 230 (Tub). When the drawn current is large, parasitic triode NPN2 among the N+ injection region 251, the substrate 220, the first well region 230 and the N+ injection region 252 is turned on to draw a current from the power supply electrode HV. Thus, a large current path is formed from the power supply electrode HV to the drain electrode Drain. This causes large power consumption, and even forms a latch-up effect in the semiconductor device to damage the chip. In the embodiment, when the negative current generated on the pin is large, the high-level control signal Vc is generated. Consequently, the voltage on the gate electrode Gate is pulled up, the channel between the source electrode Source and the drain electrode Drain is opened, and the NMOS transistor corresponding to the ESD protective semiconductor device 200 is turned on to form a current path from the reference ground (source electrode Source) to the drain electrode Drain to shunt the current from the power supply electrode HV to the drain electrode Drain. This can prevent damage of the large current on the chip, reduce the loss, prevent the latch-up effect, and improve the latch-up prevention performance and the ESD protection performance of the ESD protective semiconductor device 200.

FIG. 4 illustrates an equivalent circuit when the drain electrode Drain receives the negative current. Resistor Rnw and parasitic triode NPN1 are connected serially between the reference ground GND and the drain electrode Drain. The resistor Rnw is a bulk resistor of the first well region 230. A base of the parasitic triode NPN1 is connected to resistor Rpw. The resistor Rpw is a bulk resistor of the second well region 240, and corresponds to the body region Body. A common node between the resistor Rnw and a collector of the parasitic triode NPN1 is connected to an emitter of the parasitic triode NPN2. That is, the parasitic triode NPN2 is connected between the power supply electrode HV and the collector of the parasitic triode NPN1. A base of the parasitic triode NPN2 is connected to resistor Rsub. The resistor Rsub is a bulk resistor of the substrate 210. When the comparator circuit 300 in the embodiment is not provided or the gate electrode Gate is connected to the reference ground, and when the negative current on the pin 10 is large, there forms a current path that passes through two parasitic triodes from the power supply electrode HV to the drain electrode Drain, namely a path shown by dashed line L0 at a right side of FIG. 4. However, in the embodiment, after the comparator circuit 300 is provided, when the negative current on the pin 10 is large, the channel between the source electrode and the drain electrode is opened. This is equivalent to that resistor Rch is further connected between the reference ground GND and the drain electrode Drain. The resistor Rch is an equivalent resistor of the channel. Thus, a current path shown by dashed line L2 at a left side of FIG. 4 is formed. When the negative current on the pin is small in the latch-up experiment, the current may be discharged only through current path L1 that passes through the resistor Rnw and the parasitic triode NPN1 from the reference ground GND to the drain electrode Drain. When the negative current is increased, the current may be discharged through the current path L0 at the right side of FIG. 4. When the negative current on the pin is large, the current path L2 at the left side of FIG. 4 may further be opened to discharge the current, thereby reducing the current discharged from the current path L0. This protects the chip, reduces the loss, and prevents the latch-up effect. The comparator circuit 300 may further be provided to select the current path L2 or the current path L0 to discharge the current.

In normal ESD protection, the ESD protective semiconductor device 200 also protects the chip well. For example, in response to a positive current generated on the pin 10, a first parasitic triode among the drain electrode Drain, the second well region 240 and the first well region 230 is turned on to discharge the current. At this time, the first parasitic triode NPN includes an emitter located in the first well region 230, and a collector located in the second well region 240, and is opposite to the parasitic triode NPN1 in FIG. 4. In response to a negative current generated on the pin 10, the parasitic triode NPN1 among the first well region 230, the second well region 240 and the drain electrode Drain is turned on, and alternatively, the parasitic triode NPN2 among the N+ injection region 251, the substrate 210 and the first well region 230, and the parasitic triode NPN1 among the first well region 230, the second well region 240 and the drain electrode Drain are turned on at the same time, thereby forming a first current discharge path to discharge the current. When the voltage signal V1 on the pin 10 is less than the reference signal Vref of the preset negative voltage, the first current discharge path is formed by the parasitic triode NPN2 and the parasitic triode NPN1 or the individual parasitic triode NPN1, and the channel between the source electrode and the drain electrode is opened to form a second current discharge path.

Therefore, the ESD protective semiconductor device 200 in the embodiment can protect the chip and the device itself well in the latch-up experiment and the normal ESD protection, lower the current in the device, reduce the loss, prevent the latch-up effect, and improve the performance of the device.

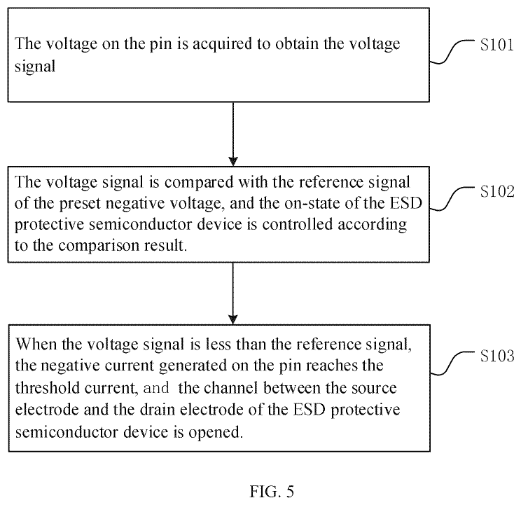

FIG. 5 illustrates a schematic flowchart of an ESD protection method according to an embodiment of the present disclosure.

As shown in FIG. 5, the present disclosure further provides the ESD protection method, which is applied to the ESD protective semiconductor device and the ESD protection apparatus shown in FIG. 2 to FIG. 4. The ESD protection method includes the following steps:

In Step S101: The voltage on the pin is acquired to obtain the voltage signal.

In Step S102: The voltage signal is compared with the reference signal of the preset negative voltage, and the on-state of the ESD protective semiconductor device is controlled according to the comparison result.

In Step S103: When the voltage signal is less than the reference signal, the negative current generated on the pin reaches the threshold current, and the channel between the source electrode and the drain electrode of the ESD protective semiconductor device is opened.

Corresponding contents have been described in detail in the embodiment shown by FIG. 2 to FIG. 4, and are not repeated herein.

In conclusion, according to the ESD protection apparatus, the ESD protective semiconductor device, and the ESD protection method provided by the present disclosure, the gate electrode of the ESD protective semiconductor device is configured to receive the control signal. The control signal is associated with the current on the pin. When the voltage signal on the pin is less than the reference signal of the preset negative voltage, the negative current generated on the pin reaches the threshold current, and the channel between the source electrode and the drain electrode of the ESD protective semiconductor device is opened through the control signal, thereby increasing the current discharge path from the source electrode to the drain electrode. That is, when the pin suffers a large negative current surge, not only can the current be discharged by a parasitic structure in the ESD protective semiconductor device, but also the channel can be opened to form another discharge path. This prevents a large current in the ESD protective semiconductor device to damage the chip, effectively prevents the latch-up effect, and improves the ESD protection performance.

Further, in response to the positive current surge on the pin, the parasitic structure can form the current discharge path from the pin to the reference ground. In response to the negative current surge on the pin, the parasitic structure can also form a current discharge path from a power supply electrode to the pin. In response to the larger negative current surge on the pin, the channel between the source electrode and the drain electrode can further be opened to increase the current discharge path from the reference ground to the pin. This enhances the ESD protection performance and the latch-up prevention performance of the ESD protective semiconductor device and the ESD protection apparatus, protects the ESD protective semiconductor device well in the latch-up experiment, and improves the discharge capacity of the ESD protective semiconductor device in normal ESD.

The embodiments of the present disclosure are described above. These embodiments neither describe all the details, nor limit the present disclosure to the specific embodiments described. Obviously, many modifications and changes may be made based on the above description. In the present specification, these embodiments are selected and specifically described to better explain the principle and practical application of the present disclosure, so that a person skilled in the art can well use the present disclosure and make modifications on the basis of the present disclosure. The present disclosure is only limited by the claims and a full scope and equivalents thereof.

1. An electro-static discharge (ESD) protection apparatus connected to a pin of a chip, and comprising:
an ESD protective semiconductor device, configured to discharge a current generated on the pin, and comprising a source electrode, a drain electrode, and a gate electrode, wherein the drain electrode is connected to the pin, and the source electrode is connected to a reference ground; and
a comparator circuit, connected between the pin and the gate electrode of the ESD protective semiconductor device, and configured to: acquire a voltage on the pin to obtain a voltage signal, compare the voltage signal with a reference signal, and control an on-state of the ESD protective semiconductor device according to a comparison result;
wherein when the voltage signal is less than the reference signal, a negative current generated on the pin reaches a threshold current, and a channel between the source electrode and the drain electrode of the ESD protective semiconductor device is opened by the comparator circuit; and the reference signal is a negative voltage.

2. The ESD protection apparatus according to claim 1, wherein the ESD protective semiconductor device is an N-channel metal-oxide-semiconductor (NMOS) device, and the reference signal is between −0.1 V and −2 V.

3. The ESD protection apparatus according to claim 1, wherein the comparator circuit comprises:
a comparator, wherein a positive input terminal and a negative input terminal of the comparator are respectively configured to receive the reference signal and the voltage signal, and an output terminal of the comparator is connected to the gate electrode; and
a resistor, connected between the pin and the negative input terminal of the comparator, and configured to: acquire the voltage on the pin to obtain the voltage signal, and transmit the voltage signal to the comparator.

4. An ESD protective semiconductor device, connected between a pin of a chip and a reference ground, and comprising:
a substrate;
a first well region, distributed in the substrate, and having a first doping type;
a second well region, located in the first well region, and having a second doping type, wherein the first doping type is opposite to the second doping type;
a plurality of first injection regions and a plurality of second injection regions, distributed at intervals in the first well region and the second well region and in gaps between the first well region and the second well region, and respectively having the first doping type and the second doping type; and
a field plate layer, located on the second well region, and configured to lead out a gate electrode, wherein a drain electrode and a source electrode are respectively led out from the first injection regions adjacent to two sides of the field plate layer;
wherein the drain electrode is connected to the pin, the source electrode is connected to the reference ground, and the gate electrode is configured to receive a control signal; and when a voltage signal on the pin is less than a reference signal of a preset negative voltage, a channel between the source electrode and the drain electrode is opened through the control signal.

5. The ESD protective semiconductor device according to claim 4, wherein the ESD protective semiconductor device is an NMOS device; the first doping type is N-type doping; and the second doping type is P-type doping.

6. The ESD protective semiconductor device according to claim 4, wherein the reference signal is between −0.1 V and −2 V.

7. The ESD protective semiconductor device according to claim 4, wherein in response to a positive current generated on the pin, a first parasitic triode among the drain electrode, the second well region and the first well region is turned on to discharge the positive current.

8. The ESD protective semiconductor device according to claim 4, wherein in response to a negative current generated on the pin, a first parasitic triode among the first well region, the second well region and the drain electrode is turned on, and alternatively, a second parasitic triode among the first injection region in the substrate, the substrate and the first well region, and the first parasitic triode among the first well region, the second well region and the drain electrode are turned on at a same time, thereby forming a first current discharge path to discharge the negative current.

9. The ESD protective semiconductor device according to claim 8, wherein when the voltage signal on the pin is less than the reference signal of the preset negative voltage, the channel between the source electrode and the drain electrode is opened to form a second current discharge path.

10. An ESD protection method applied to the ESD protective semiconductor device according to claim 4, and comprising:
acquiring the voltage on the pin to obtain the voltage signal; and
comparing the voltage signal with the reference signal of the preset negative voltage, and controlling an on-state of the ESD protective semiconductor device according to a comparison result;
wherein when the voltage signal is less than the reference signal, a negative current generated on the pin reaches a threshold current, and the channel between the source electrode and the drain electrode of the ESD protective semiconductor device is opened.

11. The ESD protection method according to claim 10, wherein the ESD protective semiconductor device is an NMOS device; the first doping type is N-type doping; and the second doping type is P-type doping.

12. The ESD protection method according to claim 10, wherein in the ESD protective semiconductor device, the reference signal is between −0.1 V and −2 V.

13. The ESD protection method according to claim 10, wherein in the ESD protective semiconductor device, in response to a positive current generated on the pin, a first parasitic triode among the drain electrode, the second well region and the first well region is turned on to discharge the positive current.

14. The ESD protection method according to claim 10, wherein in the ESD protective semiconductor device, in response to a negative current generated on the pin, a first parasitic triode among the first well region, the second well region and the drain electrode is turned on, and alternatively, a second parasitic triode among the first injection region in the substrate, the substrate and the first well region, and the first parasitic triode among the first well region, the second well region and the drain electrode are turned on at a same time, thereby forming a first current discharge path to discharge the negative current.

15. The ESD protection method according to claim 14, wherein in the ESD protective semiconductor device, when the voltage signal on the pin is less than the reference signal of the preset negative voltage, the channel between the source electrode and the drain electrode is opened to form a second current discharge path.
